(19) United States
(12) Patent Application Publication
(10) Pub. No.: US 2025/0203999 A1
(43) Pub. Date: Jun. 19, 2025

(54) SUBSTRATE-LESS PASSIVE DEVICE SOLUTION FOR BACKSIDE POWER DISTRIBUTION NETWORK

(71) Applicant: International Business Machines Corporation, Armonk, NY (US)

(72) Inventors: Ruilong Xie, Niskayuna, NY (US); Anthony I. Chou, Guilderland, NY (US); Robert Gauthier, Williston, VT (US); Kisik Choi, Watervliet, NY (US); Ravikumar Ramachandran, Pleasantville, NY (US); Terence B. Hook, Jericho Center, VT (US); PIETRO MONTANINI, Albany, NY (US)

(21) Appl. No.: 18/540,838

(22) Filed: Dec. 14, 2023

(51) Int. Cl. H01L 29/417; H01L 23/528; H01L 27/02; H01L 27/088; H01L 29/06; H01L 29/423; H01L 29/775; H01L 29/786

(52) U.S. Cl. CPC H10D 64/254; H01L 23/5286; H10D 30/43; H10D 30/6735; H10D 30/6757; H10D 62/121; H10D 84/83; H10D 89/911

(57) ABSTRACT

Frontside transistor devices and a frontside passive device are incorporated in a “substrate-less” structure having backside contacts, power rails, and power distribution network. The passive device includes two heavily doped semiconductor regions bridged by a lowly doped semiconductor region. Diffusion breaks located on the frontside may laterally confine the passive device.

### BACKGROUND

The present invention relates generally to the electrical, electronic and computer arts and, more particularly, to backside power distribution networks (BSPDN).

Backside power rails (BPR) and backside power distribution networks (BSPDN) are very attractive schemes for future complementary metal oxide semiconductor (CMOS) scaling. However, BPRs and BSPDNs require removing the substrate; therefore, the integration of passive devices (e.g. electrostatic discharge (“ESD”) diodes) typically formed in the substrate is challenging.

### BRIEF SUMMARY

Principles of the invention provide techniques for a substate-less passive device incorporated with a BSPDN. In one aspect, a structure includes a transistor and a passive device. The transistor has a first and a second source/drain region in a first direction (e.g. X-direction when viewed top down) and a gate separating the first and the second source/drain regions. The passive device has a first semiconductor region, a second semiconductor region, and a third semiconductor region laterally bridging the first and second semiconductor regions. The first semiconductor region, the second semiconductor region and the third semiconductor region are in a second direction (e.g. Y-direction when viewed top down) orthogonal to the first direction. The structure further includes a second backside contact below the second source/drain region, a frontside contact in contact with the first semiconductor region, a first backside contact in contact with the second semiconductor region, a backside interlevel dielectric embedding the first backside contact, and a pair of diffusion breaks located on either side of the passive device.

In a further aspect, a structure includes a transistor and a passive device. The transistor has a first and a second source/drain region in a first direction (e.g. X-direction when viewed top down) and a gate separating the first and the second source/drain regions. The passive device has a first semiconductor region, a second semiconductor region, and a third semiconductor region laterally bridging the first and second semiconductor regions. The first semiconductor region, the second semiconductor region and the third semiconductor region are in a second direction (e.g. Y-direction when viewed top down) orthogonal to the first direction.

In another aspect, a structure includes a transistor and a passive device. The transistor has a first and a second source/drain region in a first direction (e.g. X-direction when viewed top down) and a gate separating the first and the second source/drain regions. The passive device has a first semiconductor region, a second semiconductor region, and a third semiconductor region laterally bridging the first and second semiconductor regions. The first semiconductor region, the second semiconductor region and the third semiconductor region are in a second direction (e.g. Y-direction when viewed top down) orthogonal to the first direction. The structure further includes a second backside contact below the second source/drain region, a frontside contact in contact with the first semiconductor region, a first backside contact in contact with the second semiconductor region, a backside interlevel dielectric embedding the first backside contact, and a pair of diffusion breaks located on either side of the passive device.

In one aspect, a structure includes a transistor and a passive device. The transistor has a first and a second source/drain region and a gate separating the first and the second source/drain regions. The passive device has a first semiconductor region, a second semiconductor region, and a third semiconductor region laterally bridging the first and second semiconductor regions. The structure further includes a second backside contact below the second source/drain region, a frontside contact in contact with the first semiconductor region, a first backside contact in contact with the second semiconductor region, a backside interlevel dielectric embedding the first backside contact, and a pair of diffusion breaks located on either side of the passive device.

In another aspect, another exemplary structure includes a frontside, a backside, a transistor including a first and a second source/drain and a gate on the frontside, a passive device including a first and a second semiconductor region on the frontside, and a backside contact to the second source/drain region of the transistor, and another backside contact to the second semiconductor region of the passive device. Notably there is no silicon substrate below the first and the second source/drain and the gate of the transistor or below the first and the second semiconductor region of the passive device.

In another aspect, another exemplary structure includes a frontside, a backside, a transistor including a first and a second source/drain and a gate on the frontside, a passive device including a first and a second semiconductor region on the frontside, and a backside contact to the second source/drain region of the transistor, and another backside contact to the second semiconductor region of the passive device. Notably there is no silicon substrate below the first and the second source/drain and the gate of the transistor or below the first and the second semiconductor region of the passive device. In addition the transistor and the passive device are orthogonal to each other.

In still a further aspect, an exemplary method of forming a structure includes providing a substrate having at least two active areas, a shallow trench isolation in the substrate and between the active areas, a placeholder material embedded in portions of the active areas of the substrate, a first semiconductor region over the placeholder material and a second semiconductor region over the placeholder material; forming a conformal protective liner over the first semiconductor region and second semiconductor region; removing the conformal protective liner between the first and second semiconductor regions; forming a semiconductor bridge between the first and second semiconductor regions; forming a diffusion break perpendicular to the active areas on each side of the first and second semiconductor regions and the semiconductor bridge; forming a frontside contact to the first semiconductor region; and forming a backside contact to the second semiconductor region.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments allow integration of passive devices in structures using backside power distribution networks (BSPDN).

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1A-1D depict, in top-down and corresponding cross-sectional views, a starting point in making an exemplary structure according to aspects of the invention;

FIGS. 2A-2B are cross-sections of FIGS. 1C-1D, respectively, after forming a protective liner on the frontside according to aspects of the invention;

FIGS. 3A-3B are cross-sections of FIGS. 2A-2B, respectively, after removing a portion of the protective layer according to aspects of the invention;

FIGS. 4A-4B are cross-sections of FIGS. 3A-3B, respectively, after forming a semiconductor bridge on the frontside according to aspects of the invention;

FIGS. 5A-5B are cross-sections of FIGS. 4A-4B, respectively, after forming a co-planar insulator on the frontside according to aspects of the invention;

FIGS. 6A-6B are top-down views of the exemplary structure after forming frontside contact, diffusion breaks and back-end of line interconnects, and attaching a carrier wafer to the front side, according to aspects of the invention;

FIGS. 6C-6D are cross-sections of FIGS. 5A-5B, respectively, after forming frontside contact, diffusion breaks and back-end of line interconnects, and attaching a carrier wafer to the front side, according to aspects of the invention;

FIGS. 7A-7B are cross-sections of FIGS. 6C-6D, respectively, after removing the substrate according to aspects of the invention;

FIGS. 8A-8B are cross-sections of FIGS. 7A-7B, respectively, after forming and patterning a backside dielectric layer according to aspects of the invention;

FIGS. 9A-9B are cross-sections of FIGS. 8A-8B, respectively, after forming backside dielectric contacts according to aspects of the invention;

FIGS. 10A-10B are cross-sections of FIGS. 9A-9B, respectively, after forming backside power rails and backside power distribution networks according to aspects of the invention; and

FIGS. 11A-11B are simplified top-down views of FIGS. 10A-10B, respectively, depicting frontside contacts, backside contacts, diffusion breaks, transistor elements and passive device elements according to aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

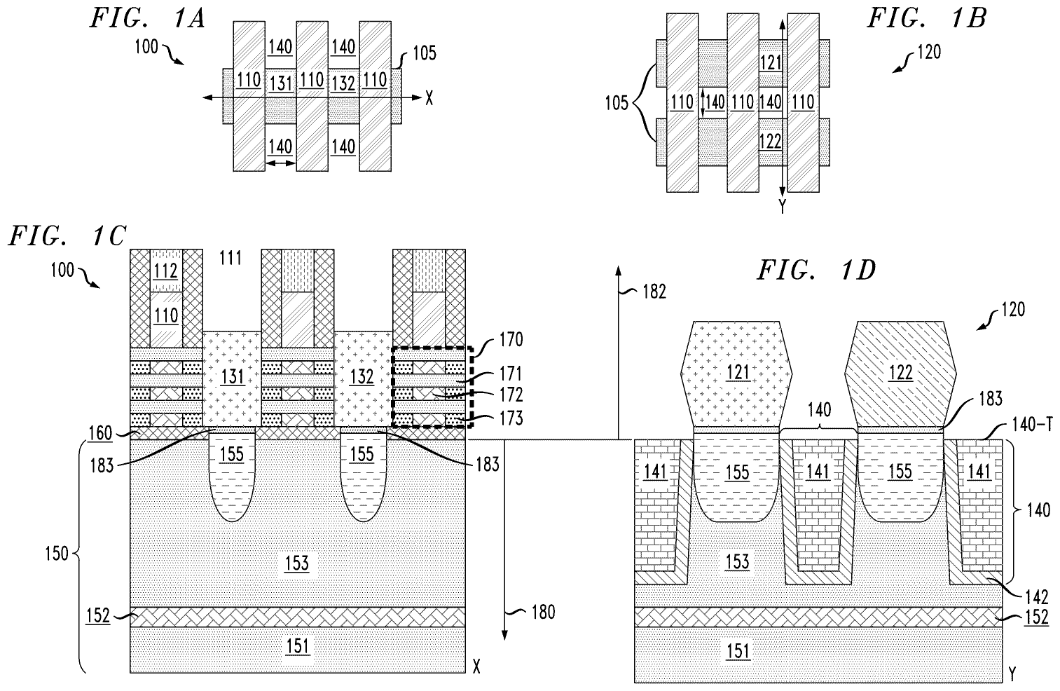

Aspects of the invention provide techniques for incorporating a passive device, such as an electrostatic discharge device (“ESD”), in a semiconductor structure including a transistor and having direct backside contacts (DBC). Refer now to FIGS. 1A and 1B, which are top-down views of a general layout of an integrated circuit structure at a starting point in accordance with an exemplary embodiment. Here, FIG. 1A shows a transistor region 100 of the structure and FIG. 1B shows a region having a passive device region 120. In both instances there is an active area 105 and dummy gates 110 perpendicular to the active area 105. The area between adjacent active areas 105 are shallow trench isolation (STI) 140 regions. The active area 105 of the transistor region 100 includes first source/drain 131 and second source/drain 132 regions (see FIG. 1A). The active area 105 of the passive device region 120 includes first heavily doped semiconductor 121 region and second heavily doped semiconductor 122 region which can be formed epitaxially (see FIG. 1B).

FIGS. 1C-1D are cross-sections of FIGS. 1A-1B of transistor region 100 and passive device region 120 in the X and Y directions, respectively, during a starting point in the process of making an exemplary embodiment. Referring to FIGS. 1C-1D, both the transistor region 100 and the passive device are over a substrate 150 which includes a lower portion 151, an etch stop layer 152 and an upper portion 153. The substrate's lower and upper portions 151/153 can, for example, be silicon and the etch stop layer can, for example, be silicon germanium. Within the substrate, placeholders 155 are formed under the first source/drain 131 and second source/drain 132 and under the first heavily doped semiconductor 121 and second heavily doped semiconductor 122 regions. The placeholders 155 can, for example, be silicon germanium.

Referring to FIG. 1C, above the substrate 150 is a bottom dielectric layer 160 which can, for example, be SiN, SiOC, SiOCN or any other material which allows etch selectivity with SiO₂. Above the bottom dielectric layer 160 are a nanostack 170 including future channel material 171 and dummy gate structures. The nanostack includes alternating layers of a sacrificial material 172 and channel material 171. Here, the sacrificial material has been recessed and inner spacers 173 have been formed. Channel material 171 can, for example, be silicon, sacrificial material 172 can, for example, be silicon germanium, and inner spacers 173 can, for example, be SiN, SiBCN, or SiOC. Above the nanostack 170 is the dummy gate structure including dummy gate 110 which can, for example, be amorphous silicon, gate spacers 111 which can, for example, be SiN, SiOC, SiOCN or any other material which allows etch selectivity with SiO₂, and hard mask 112 which can, for example, be SiN, SiOC, SiOCN. Between the gate structures on a frontside 182 are first source/drain 131 and second source/drain 132 regions which can be silicon doped for the appropriate polarity of the transistor (e.g. NFET or PFET).

Referring to FIG. 1D, in the upper portion 153 of the substrate 150 are shallow trench isolations (“STI”) 140 including an STI liner 142 and STI fill 141 which may be a silicon nitride and a silicon oxide, respectively. Also, between STIs, and largely in the upper portion 153 of the substrate, are placeholders 155. Above the placeholders 155, on the frontside 182 are first heavily doped semiconductor 121 region and second heavily doped semiconductor region 122. The doping level may be from about 1×10¹⁹ cm⁻³ to about 9×10²¹ cm⁻³. The first heavily doped semiconductor 121 region and second heavily doped semiconductor 122 region, are heavily doped semiconductors (e.g. silicon or silicon germanium), they can be oppositely doped (i.e. one p-doped and the other n-doped). Vertically intervening between the first and second heavily doped semiconductor regions and the placeholders 155 may be a thin silicon layer 183.

Referring to FIGS. 1C and 1D, a frontside 182 and backside 180 of the structures is noted. At this starting point in the process, the backside 180 for the transistor region 100 (FIG. 1C) is from the top of the upper portion 153 of the substrate and below. Accordingly, the frontside 182 is from the bottom dielectric layer 160 upwards. Similarly, the backside 180 for the passive device region 120 (FIG. 1D) is from the top 140-T of the STI 140 and below. Accordingly, the frontside 182 is from the top 140-T of the STI 140 upwards.

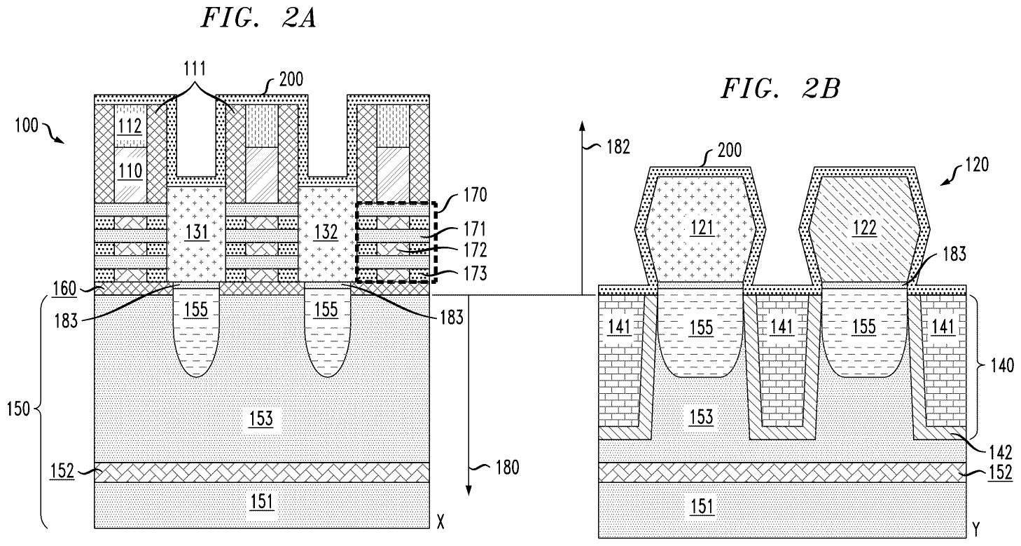

In a next step, FIGS. 2A and 2B show cross-sections of FIGS. 1C and 1D, respectively after conformally depositing a protective liner 200 of thin silicon nitride (or other dielectrics, such as SiBCN, SiOCN, SiOC, SiC, etc.) on the frontside 182.

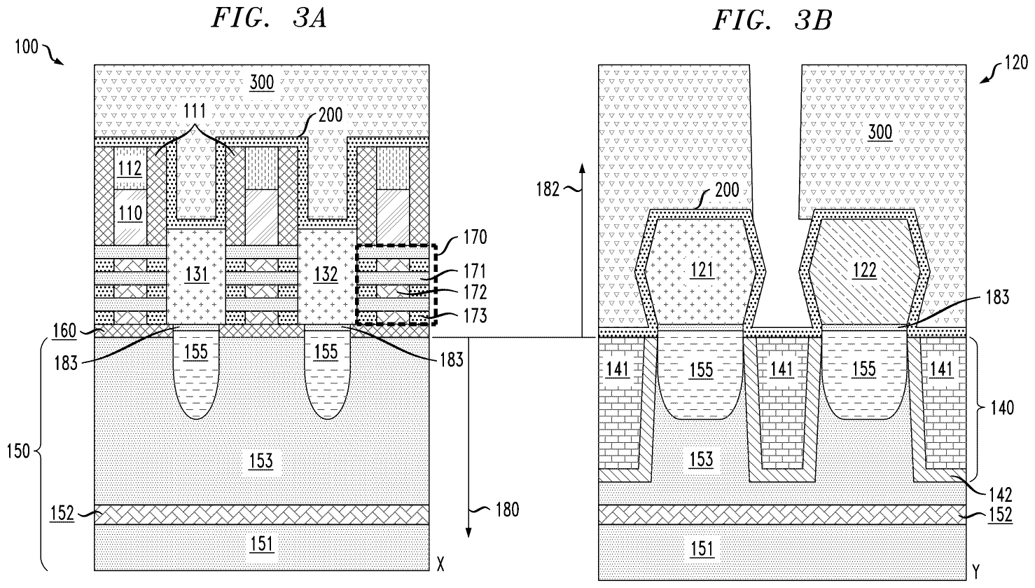

FIGS. 3A and 3B show the masking of the transistor region 100 while the passive device region 120 goes through a series of lithographic and etch steps to expose and selectively remove the protective liner 200 from adjacent sidewalls of the first heavily doped semiconductor 121 and the second heavily doped semiconductor 122 regions and the top 140-T of the STI 140 between the adjacent sidewalls. The series of lithographic steps may include forming an optical planarization layer 300, an antireflective coating and a photoresist.

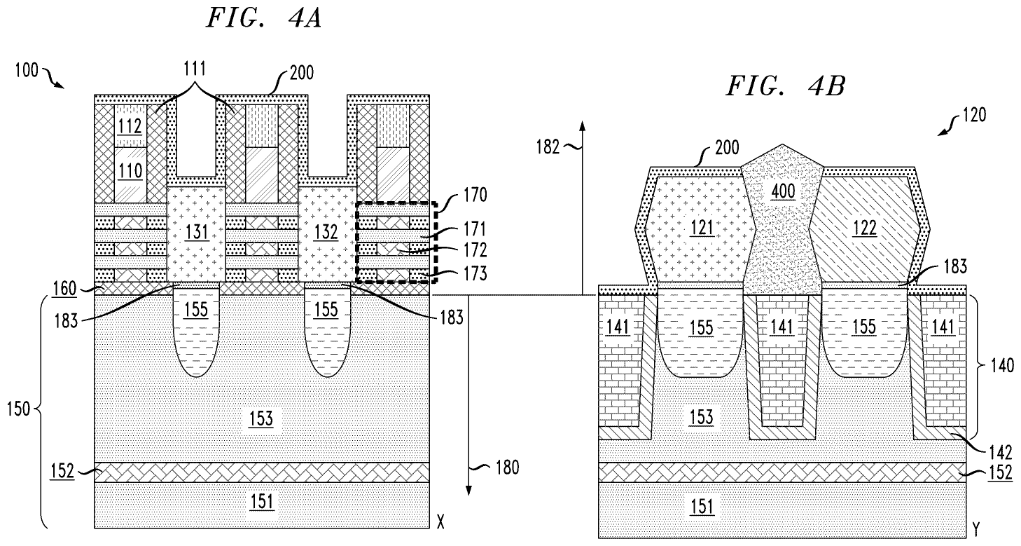

FIGS. 4A and 4B show the results of unmasking the transistor region 100 after which a third semiconductor region which is lightly doped or undoped can be epitaxially grown on the frontside 182 on exposed surfaces of the first heavily doped semiconductor 121 and the second heavily doped semiconductor 122 regions in the passive device region 120 such that a lightly doped semiconductor bridge 400 is formed connecting the first and second heavily doped semiconductor regions. The lightly doped semiconductor bridge 400 may be doped from about 0 to about 5×10¹⁸ cm⁻³. The lightly doped semiconductor bridge 400 may be either n or p doped. The lightly doped semiconductor bridge 400 may be either silicon or silicon germanium.

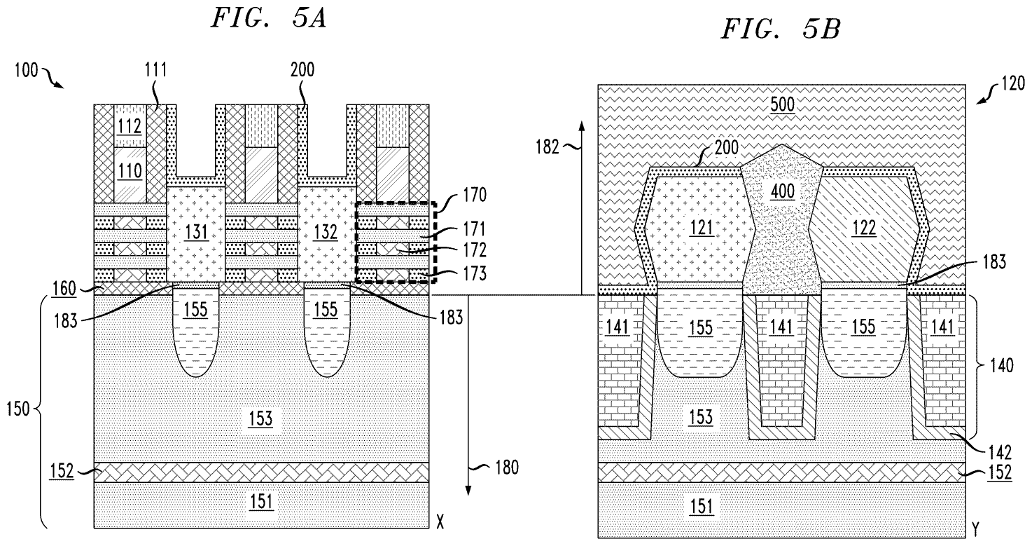

FIGS. 5A and 5B show the results of depositing a middle of line dielectric 500 layer and planarizing so that it is co-planar with the hard mask 112. Normally, an MOL dielectric on top of the epitaxial semiconductor would cause concern of dopant loss or silicon germanium oxidation, but due to the light doping of the bridge 400, the concern is obviated. MOL dielectric may be a combination of nitride, oxide or low-k oxide.

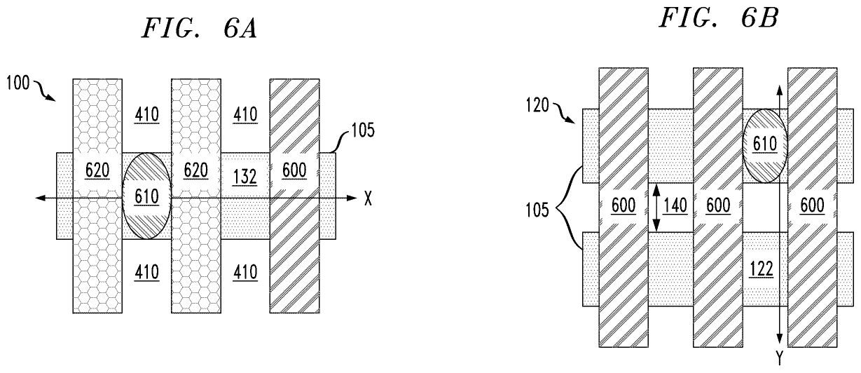

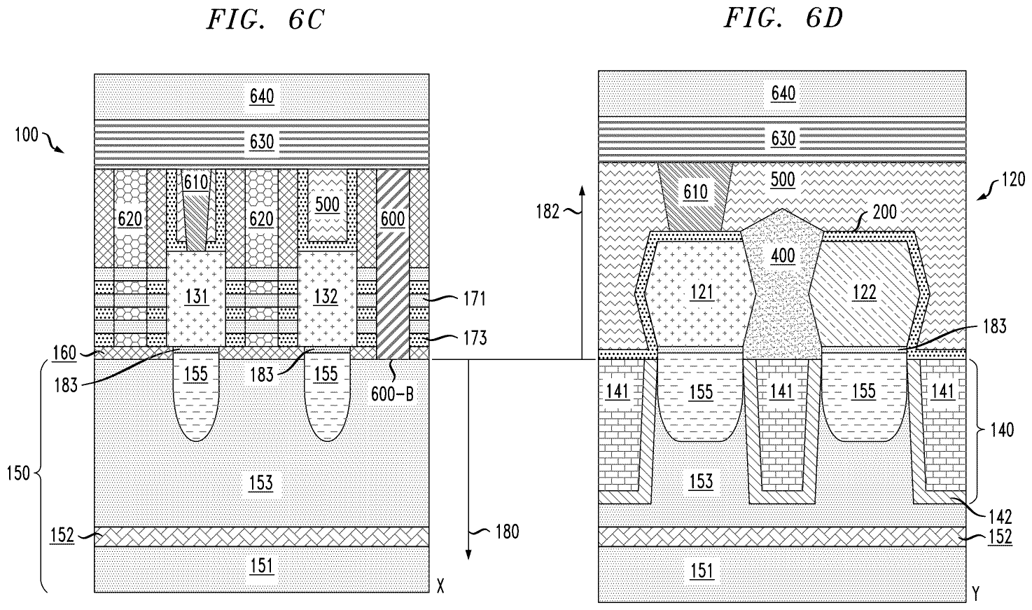

FIGS. 6A-6D show the results of many steps including diffusion break 600 formation, replacement metal gate 620 formation, frontside contact 610 formation, backend of line interconnect 630 formation and attachment of a carrier wafer 640 to the frontside 182. A diffusion break 600 is shown in the top-down view FIG. 6A of the transistor region 100 and in the cross-section view FIG. 6C. The diffusion break 600 is formed in a location formerly occupied by one of the dummy gates 110. In FIG. 6C, the bottom 600-B of the diffusion break 600 lands on the upper portion 153 of the substrate 150, or stated another way, the diffusion break 600 is completely (allowing for some variation consistent with typical process tolerances) in the frontside 182, however, the diffusion break, in other embodiments can etch into the upper portion 153 of the substrate. Referring to FIG. 6B, the passive device region 120 also replaced dummy gates 110 with diffusion breaks 600. A pair of the diffusion breaks 600 run along opposite sides of the first heavily doped semiconductor 121/second heavily doped semiconductor 122 regions and their lightly doped bridge 400. While the cross-section of the passive device region 120 does not show the diffusion breaks 600 as they are located in front and behind the page, their structure is similar in the diffusion breaks discussed in conjunction with FIG. 6C.

The replacement metal gate 620 process entails removing the dummy gate 110 amorphous silicon and removing sacrificial material 172 in the channel and forming an interfacial oxide layer, high-k dielectric, workfunction material and a metal fill in its place. A frontside contact 610 is made to each of the first source/drain region 131 of the transistor and to the first heavily doped semiconductor 121 of the passive device. The frontside contact 610 may include a silicide liner, an adhesion metal liner and a low resistance metal fill. After formation, back end of line interconnects 630 are made and a carrier wafer 640 attached in preparation for flipping the structure and removing the substrate 150.

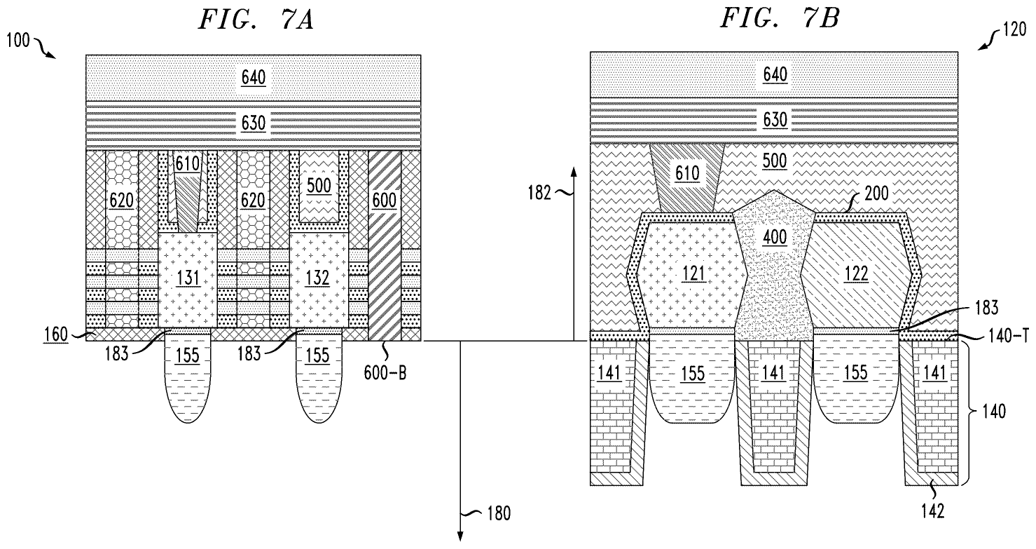

Refer to FIGS. 7A and 7B, which are cross-sections of FIGS. 6C and 6D of the transistor region 100 and passive device region 120 after removing the substrate 150. At this point the regions have become “substrate-less”. The substrate is removed by selectively removing lower bulk portion 151 of the substrate stopping on etch stop layer 152, then removing etch stop layer 152 followed by selectively removing the upper portion 153 of the substrate.

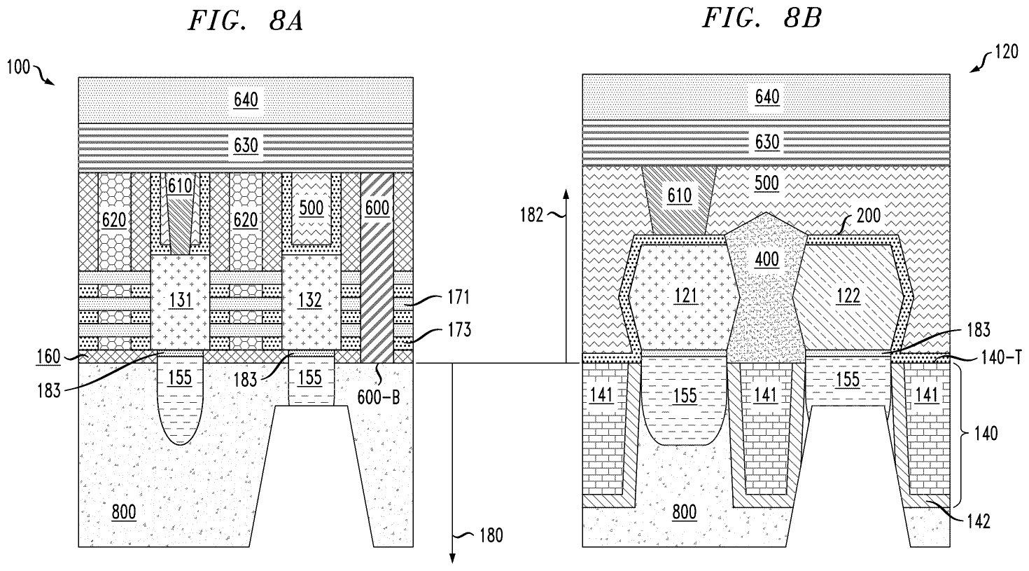

Referring to FIGS. 8A and 8B, a backside interlevel dielectric 800 is formed on the backside 180 and patterned to expose and etch a portion of the placeholder 155 material under the second source/drain 132 region and the second heavily doped semiconductor 122 region. While still considered “substrate-less,” note that the backside interlevel dielectric 800 essentially replaces the substrate 150 in the transistor region 100 and passive device region 120.

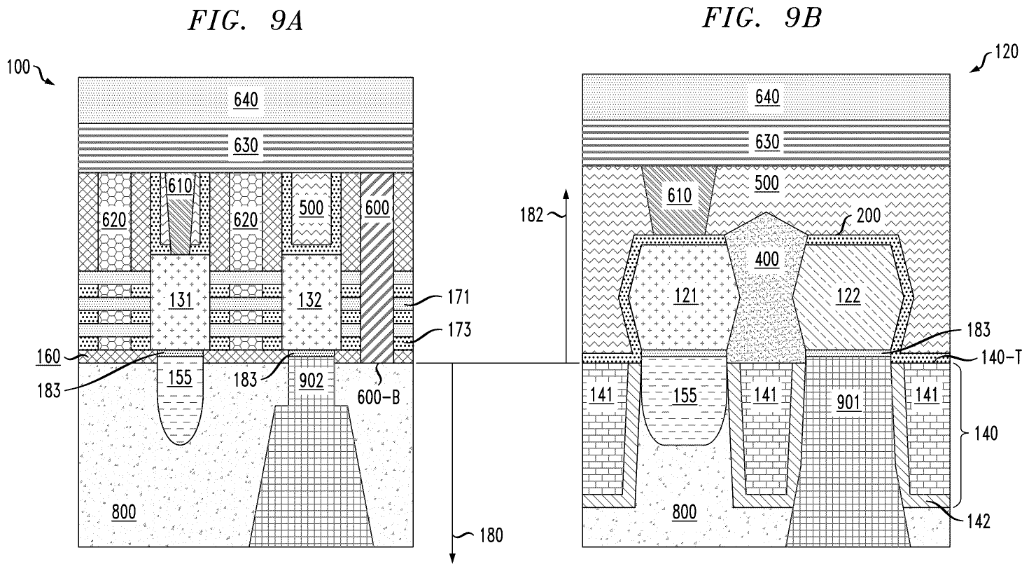

Referring to FIGS. 9A and 9B, the placeholder 155 material exposed in FIG. 8 is removed and backside contacts 902 and 901 are made to the second source/drain 132 region and the second heavily doped semiconductor 122, respectively.

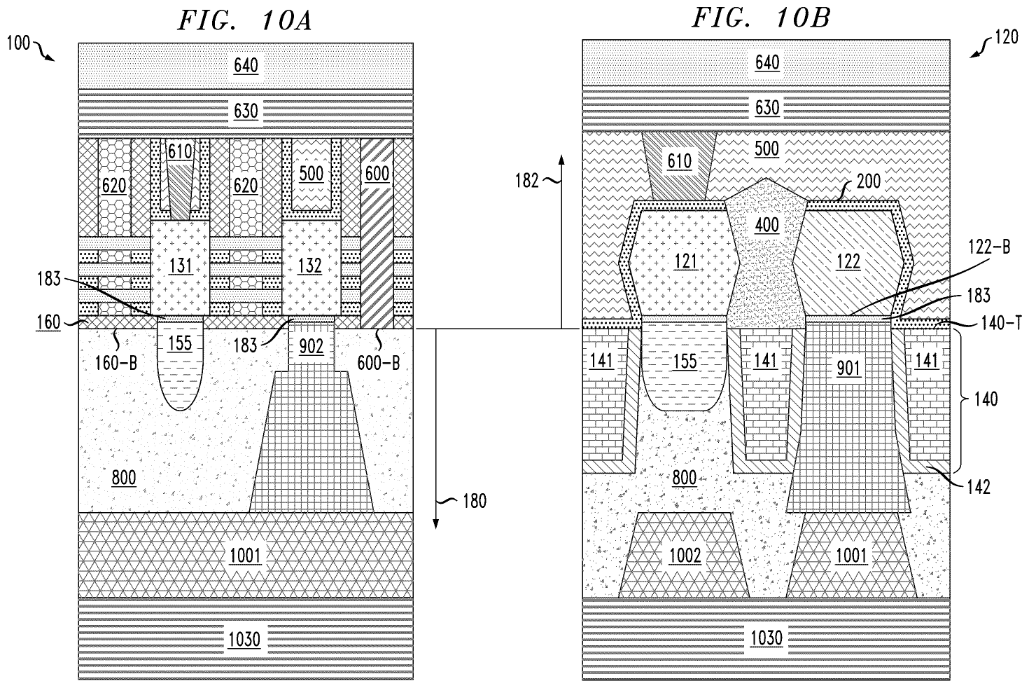

Referring to FIGS. 10A and 10B, additional backside interlevel dielectric 800 layers can be deposited and first and second backside power rails 1001 and 1002 formed in it. The first backside power rails 1001 contact the backside contact 902 in the transistor region 100 and the backside contact 901 in the passive device region 120. The first backside power rails 1001 may serve as Vdd. The second backside power rail 1002 may serve as Vss. Both the first and second backside power rails 1001 and 1002 connect to the backside distribution network 1030.

Referring to FIG. 10A, in this “substrate-less” transistor region 100 in which the backside interlevel dielectric 800 replaced the substrate 150, the frontside 182 is from the bottom 160-B of the bottom dielectric layer 160 upwards. The backside 180 is from the bottom 160-B of the bottom dielectric layer 160 downwards. Therefore, each element of the transistor, namely first source/drain 131 and second source/drain 132 regions and replacement metal gate 620 are in the frontside 182. As mentioned before, the bottom 600-B of the diffusion break 600 is also in the frontside (within reasonable process tolerances).

Referring to FIG. 10B, in this “substrate-less” passive device region 120 in which the backside interlevel dielectric 800 replaced the substrate 150, the frontside 182 is from the top 140-T of the STI 140 upwards. The backside 180 is from the top 140-T of the STI 140 downwards. Therefore, each element of the passive device, namely first heavily doped semiconductor 121 region, the second heavily doped semiconductor 122 region, and the lightly doped semiconductor bridge 400 are in the frontside 182. For example, the bottom surface 122-B of the second heavily doped semiconductor 122 region is on the frontside 182. As mentioned earlier, the bottom 600-B of the diffusion break 600 is also in the frontside (within reasonable process tolerances).

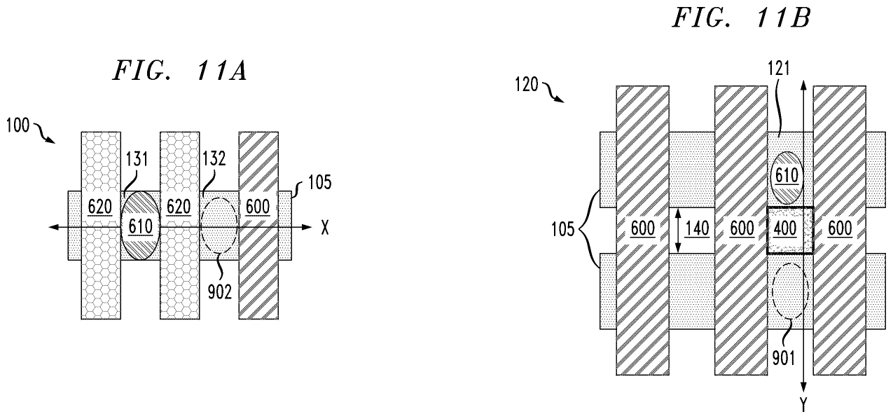

FIGS. 11A-11B are simplified top-down views of FIGS. 10A-10B, respectively, depicting frontside contacts 610, backside contacts 902 and 901, diffusion breaks 600, transistor elements, and passive device elements according to aspects of the invention. Transistor elements can include first source/drain 131 and second source/drain 132 regions and replacement metal gates 620. Passive device elements can include first heavily doped semiconductor 121 region, second heavily doped semiconductor 122 region, and lightly doped 400 semiconductor regions. Referring to FIG. 11A, the transistor elements run in a first direction while the passive device elements run in an orthogonal direction (see FIG. 11B). Accordingly, no passive device current runs through the replacement metal gates 620 of the transistor.

In summary, aspects of the invention include monolithic transistor and passive device. The transistor has a first source/drain 131 region and a second source/drain 132 region; and a gate 620 separating the first source/drain 131 and the second source/drain 132 regions. The first and second source/drain regions and the gate are in a first direction (e.g. the X-direction when viewed top down). The passive device has a first heavily doped semiconductor 121 region, a second heavily doped semiconductor 122 region and a lightly doped semiconductor bridge 400 (also referred to as the third semiconductor region) laterally bridging the first heavily doped semiconductor 121 and second heavily doped semiconductor 122 regions. The first semiconductor region, the second semiconductor region and the third semiconductor region are in a second direction orthogonal to the transistor direction (e.g. the Y-direction when viewed to down). The structure also includes a second backside contact 902 below the second source/drain 132 region, a frontside contact 610 in contact with the first heavily doped semiconductor 121 region, a first backside contact 901 in contact with the second heavily doped semiconductor 122 region, a backside interlevel dielectric 800 embedding the first backside contact 901 and a pair of diffusion breaks 600 located on either side of the passive device. (See FIGS. 10A&B and FIG. 11B).

The structure can also include a protective liner 200 in contact with the first heavily doped semiconductor 121 and second heavily doped semiconductor 122r regions and a middle of line dielectric 500 over the protective liner 200 and in contact with the third semiconductor region 400. (See FIG. 10B)

The first heavily doped semiconductor 121 and second heavily doped semiconductor 122 regions can be oppositely doped. The first heavily doped semiconductor 121 region can have a dopant concentration from 1×10¹⁹ cm⁻³ to 9×10²¹ cm⁻³ and ranges therebetween. The third semiconductor region 400, is lightly doped compared with the first and second semiconductor regions and may have a dopant concentration of 0 to 5×10¹⁸ cm⁻³. Therefore, the first heavily doped semiconductor region 121 has a dopant concentration at least 2 times that of the third semiconductor region.

Under the transistor and the passive device, can be additional features. For example, the passive device can be above the backside interlevel dielectric 800 (see FIG. 10B). And referring to FIGS. 10A&B, placeholders 155 can be under the first source/drain 131 and under the first heavily doped semiconductor region 121.

In further summary, aspects of the invention include a structure having a frontside 182, a backside 180, a transistor which includes a first source/drain 131 region and a second source/drain 132 region and a gate 620 on the frontside 182, a passive device which includes a first heavily doped semiconductor 121 and a second heavily doped semiconductor 122 region on the frontside 182, and a backside contact 902 to the second source/drain region of the transistor, and another backside contact 901 to the second heavily doped semiconductor 122 region of the passive device. Notably, there is no silicon substrate 150 below the first 131 and the second source/drain 132 and the gate 620 of the transistor or below the first heavily doped semiconductor 121 and the second heavily doped semiconductor 122 region of the passive device. (See FIGS. 10&10B).

With further reference to FIGS. 10A&1B, the structure can include a frontside contact 610 to the first source/drain region 131 of the transistor and another frontside contact 610 to the first heavily doped semiconductor region 121 of the passive device. Additionally, placeholders 155 under the first source/drain region 131 of the transistor, and under the first heavily doped semiconductor region 121 of the passive device can make up the structure.

Referring to FIG. 10B, advantageously, a semiconductor bridge 400 can laterally connect the first heavily doped semiconductor 121 and second heavily doped semiconductor 122 regions of the passive device. The semiconductor bridge 400 can have a lower dopant concentration than the first heavily doped semiconductor 121 region of the passive device. A shallow trench isolation 140 can be located under the semiconductor bridge 400.

The structure can include a conformal protective liner 200 in contact with the first heavily doped semiconductor 121 and second heavily doped semiconductor 122 regions of the passive device, and a middle of line dielectric 500 over the conformal protective liner 200 and in contact with the semiconductor bridge 400 (see FIGS. 10A&B). Additionally, a pair of diffusion breaks 600 can confine the passive device by being located on the frontside 182 on either side of the passive device: (see FIG. 11B).

Optionally, the structure of claim 16, wherein the second semiconductor region of the passive device has a bottom surface, and wherein the shallow trench isolation has a top surface located at or below the bottom surface of the second semiconductor region of the passive device. (see FIG. 10B).

] In summary of aspects of the invention, a method of forming a structure may include providing a substrate 150 having at least two active areas 105, a shallow trench isolation 140 in the substrate and between the active areas 105, placeholders 155 embedded in portions of the active areas of the substrate, a first heavily doped semiconductor 121 over one of the placeholders 155 and a second heavily doped semiconductor 122 over another of the placeholders 155 (FIGS. 1B & 1D); forming a conformal protective liner 200 over the first heavily doped semiconductor region 121 and second heavily doped semiconductor region 122 (FIG. 2B); removing the conformal protective liner 200 between the first heavily doped semiconductor 121 and second heavily doped semiconductor 122 regions (FIG. 3B); forming a semiconductor bridge between 400 the first heavily doped semiconductor 121 and second heavily doped semiconductor 122 regions (FIG. 4B); forming a diffusion break 600 perpendicular to the active areas 105 on each side of the first heavily doped semiconductor 121 and second heavily doped semiconductor 122 regions and the semiconductor bridge 400 (FIG. 6B); forming a frontside contact 610 to the first semiconductor region 12 (FIGS. 6B & D); and forming a backside contact 901 to the second semiconductor region 12. (FIG. 9B).

Additionally, method steps can include replacing the substrate 150 with a backside interlevel dielectric layer 800 (FIGS. 6-8); forming a second shallow trench isolation 140 adjacent one of the active areas 105; forming a protective liner 200 over the shallow trench isolation 140 and the second shallow trench isolation 140; removing the protective liner 200 from the shallow trench isolation 140; and forming a bottom dielectric layer 160 on the substrate 150 wherein a bottom 600-B of the diffusion break 600 is co-planar with a bottom 160-B of the bottom dielectric layer 160 (FIGS. 8A and 10A).

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A structure comprising:
a transistor including:
a first and a second source/drain region; and
a gate separating the first and the second source/drain regions;
wherein the first and second source/drain regions and the gate are in a first direction;
a passive device including:
a first semiconductor region;
a second semiconductor region; and
a third semiconductor region laterally bridging the first and second semiconductor regions;
wherein the first semiconductor region, the second semiconductor region and the third semiconductor region are in a second direction;
a second backside contact below the second source/drain region;
a frontside contact in contact with the first semiconductor region;
a first backside contact in contact with the second semiconductor region;
a backside interlevel dielectric embedding the first backside contact; and
a pair of diffusion breaks located on either side of the passive device;
wherein the first direction is orthogonal to the second.

2. The structure of claim 1, further comprising:
a protective liner in contact with the first and second semiconductor regions; and
a middle of line dielectric over the protective liner and in contact with the third semiconductor region.

3. The structure of claim 1, wherein the first semiconductor region and the second semiconductor region are oppositely doped.

4. The structure of claim 1, wherein the first semiconductor region has a dopant concentration from 1×10¹⁹ cm⁻³ to 9×10²¹ cm⁻³.

5. The structure of claim 1, wherein the third semiconductor region has a dopant concentration of 0 to 5×10¹⁸ cm⁻³.

6. The structure of claim 1, wherein the first semiconductor region has a dopant concentration at least two times that of the third semiconductor region.

7. The structure of claim 1, wherein the passive device is above the backside interlevel dielectric.

8. The structure of claim 1, further comprising:
a first placeholder material under the first source/drain; and
a second placeholder material under the first semiconductor region.

9. A semiconductor structure comprising:
a frontside;
a backside;
a transistor including a first and a second source/drain and a gate on the frontside;
a passive device including a first and a second semiconductor region on the frontside;
a backside contact to the second source/drain region of the transistor; and
another backside contact to the second semiconductor region of the passive device;
wherein there is no silicon substrate below the first and the second source/drain and the gate of the transistor; and
wherein there is no silicon substrate below the first and the second semiconductor region of the passive device.

10. The structure of claim 9, further comprising:
a frontside contact to the first source/drain region of the transistor; and
another frontside contact to the first semiconductor region of the passive device.

11. The structure of claim 10, further comprising:
a placeholder material under the first source/drain region of the transistor; and
another placeholder material under the first semiconductor region of the passive device.

12. The structure of claim 9, further comprising:
a semiconductor bridge laterally connecting the first and second semiconductor regions of the passive device.

13. The structure of claim 12, wherein the semiconductor bridge has a lower dopant concentration than the first semiconductor region of the passive device.

14. The structure of claim 12, further comprising:
a conformal protective liner in contact with the first and second semiconductor regions of the passive device; and
a middle of line dielectric over the conformal protective liner and in contact with the semiconductor bridge.

15. The structure of claim 12, further comprising:
a pair of diffusion breaks located on the frontside on either side of the passive device.

16. The structure of claim 12, further comprising:
a shallow trench isolation located under the semiconductor bridge.

17. The structure of claim 16, wherein the second semiconductor region of the passive device has a bottom surface, and wherein the shallow trench isolation has a top surface located at or below the bottom surface of the second semiconductor region of the passive device.

18. A method of forming a semiconductor structure, comprising:
providing a substrate having:
at least two active areas;
a shallow trench isolation in the substrate and between the active areas;
a placeholder material embedded in portions of the active areas of the substrate;
a first semiconductor region over the placeholder material; and
a second semiconductor region over the placeholder material;
forming a conformal protective liner over the first semiconductor region and second semiconductor region;
removing the conformal protective liner between the first and second semiconductor regions;
forming a semiconductor bridge between the first and second semiconductor regions;
forming a diffusion break perpendicular to the active areas on each side of the first and second semiconductor regions and the semiconductor bridge;
forming a frontside contact to the first semiconductor region; and
forming a backside contact to the second semiconductor region.

19. The method of claim 18, further comprising replacing the substrate with a backside interlevel dielectric layer.

20. The method of claim 19, further comprising:
forming a second shallow trench isolation adjacent one of the active areas;
forming a protective liner over the shallow trench isolation and the second shallow trench isolation;
removing the protective liner from the shallow trench isolation; and
forming a bottom dielectric layer on the substrate wherein a bottom of the diffusion break is co-planar with a bottom of the bottom dielectric layer.

21. A semiconductor structure comprising:
a transistor including:
a first and a second source/drain region; and
a gate separating the first and the second source/drain regions;
a passive device including:
a first semiconductor region;
a second semiconductor region; and
a third semiconductor region laterally bridging the first and second semiconductor regions;
a second backside contact below the second source/drain region;
a frontside contact in contact with the first semiconductor region;
a first backside contact in contact with the second semiconductor region;
a backside interlevel dielectric embedding the first backside contact; and
a pair of diffusion breaks located on either side of the passive device.

22. The semiconductor structure of claim 21 wherein the third semiconductor region has a dopant concentration less than the first semiconductor region.

23. A semiconductor structure comprising:
a frontside;
a backside;
a transistor including a first and a second source/drain and a gate on the frontside;
a passive device including a first and a second semiconductor region on the frontside;
a backside contact to the second source/drain region of the transistor; and
another backside contact to the second semiconductor region of the passive device;
wherein there is no silicon substrate below the first and the second source/drain and the gate of the transistor;
wherein there is no silicon substrate below the first and the second semiconductor region of the passive device; and
wherein the passive device is orthogonal to the transistor.

24. The semiconductor structure of claim 23 further comprising:
a semiconductor bridge laterally connecting the first and second semiconductor regions of the passive device.

25. The semiconductor structure of claim 23 further comprising:
a pair of diffusion breaks located on either side of the passive device.
